(19) United States
(12) Patent Application Publication
(10) Pub. No.: US 2023/0387717 A1
(43) Pub. Date: Nov. 30, 2023

(54) ELECTRICAL METER WITH DUAL ANALOG-TO-DIGITAL CONVERTERS

(71) Applicant: Sense Labs, Inc., Cambridge, MA (US)

(72) Inventors: Michael S. Phillips, Belmont, MA (US); Christopher M. Micali, Concord, MA (US); John Andrew Watlington, Acton, MA (US); Jonah Wyman Petri, Somerville, MA (US)

(21) Appl. No.: 18/321,355

(22) Filed: May 22, 2023

Related U.S. Application Data
(60) Provisional application No. 63/345,739, filed on May 25, 2022.

(51) Int. Cl. H02J 13/00

(52) U.S. Cl. CPC H02J 13/00002

(57) ABSTRACT

An electrical meter may have more than one analog-to-digital converter to allow the electrical meter to provide additional functionality. A first analog-to-digital converter (ADC) may be used by a metrology component of an electrical meter to determine an amount of energy consumption corresponding to power provided via the electrical meter. The electrical mater may have a second ADC that is separate from the first ADC used by the metrology component. The second ADC may have a different configuration from the first ADC, such as a different sampling rate or bit depth. The second ADC may be used to provide additional functionality, such as determining information about individual devices receiving power via the electrical meter.

### CROSS-REFERENCE TO RELATED APPLICATION

This application claims the benefit of priority to U.S. Provisional Patent Application Ser. No. 63/345,739, filed May 25, 2022, and entitled “ELECTRICAL METER WITH DUAL ANALOG-TO-DIGITAL CONVERTERS” (SAGE-0008-P01).

The aforementioned applications/patents are hereby incorporated by reference in their entirety for all purposes.

### BACKGROUND

Electric companies provide electricity to their customers and need to measure the amount of power or electricity provided to individual customers for billing purposes. Electrical meters may be used for this purpose. Electrical meters may use electrical sensors to measure aspects of electrical consumption, such as the voltage and current of the electricity provided to customers.

Older electrical meters may be implemented using analog or mechanical techniques. The amount of electricity consumed may cause a mechanical process, such as the spinning of a dial that records the amount of electricity consumed. Newer electrical meters may use digital processing. The outputs of the electrical sensors may be converted to digital signals, and the digital signals may be processed to determine the amount of electricity consumed. The amount of electricity consumed may be stored on the meter or may be transmitted (e.g., wirelessly) to the electric company.

### SUMMARY

In some aspects, the techniques described herein relate to an electrical meter, including: an electrical sensor for measuring an electrical property of a power line to a building; a metrology component; a first analog-to-digital converter that processes an analog output of the electrical sensor to generate a first digital signal, wherein the first digital signal has a first sampling rate and the first digital signal is used by the metrology component of the electrical meter; a first processing component of the metrology component that processes the first digital signal to determine an energy consumption value for devices of the building; a second analog-to-digital converter that processes the analog output of the electrical sensor to generate a second digital signal, wherein the second digital signal has a second sampling rate that is different from the first sampling rate and the second digital signal is not used by the metrology component of the electrical meter; and a second processing component that processes the second digital signal to determine first information corresponding to power consumption.

In some aspects, the techniques described herein relate to an electrical meter, wherein the first processing component is a first signal processing component.

In some aspects, the techniques described herein relate to an electrical meter, wherein the electrical sensor is a current sensor.

In some aspects, the techniques described herein relate to an electrical meter, wherein the first analog-to-digital converter has a first bit depth and the second analog-to-digital converter has a second bit depth that is different from the first bit depth.

In some aspects, the techniques described herein relate to an electrical meter, wherein the first analog-to-digital converter is part of the metrology component and the second analog-to-digital converter is external to the metrology component.

In some aspects, the techniques described herein relate to an electrical meter, wherein the first information corresponding to power consumption includes information about operation of an electrical grid connected to the electrical meter.

In some aspects, the techniques described herein relate to an electrical meter, wherein the first information corresponding to power consumption includes information about a location of a power outage.

In some aspects, the techniques described herein relate to an electrical meter, wherein the first information corresponding to power consumption includes identifying information about a first device in the building.

In some aspects, the techniques described herein relate to a system including: an electrical sensor for measuring an electrical property of a power line to a building; a metrology component; a first analog-to-digital converter that processes an analog output of the electrical sensor to generate a first digital signal, wherein the first digital signal has a first sampling rate and the first digital signal is used by the metrology component of an electrical meter; a first processing component of the metrology component that processes the first digital signal to determine an energy consumption value for devices of the building; a second analog-to-digital converter that processes the analog output of the electrical sensor to generate a second digital signal, wherein the second digital signal has a second sampling rate that is different from the first sampling rate and the second digital signal is not used by the metrology component of the electrical meter; and a second processing component that processes the second digital signal to determine first information corresponding to power consumption.

In some aspects, the techniques described herein relate to a system, wherein the first information corresponding to power consumption includes information about a state change of a first device in the building.

In some aspects, the techniques described herein relate to a system, wherein the first information corresponding to power consumption includes (i) energy consumption of a first device in the building and (ii) energy consumption of a second device in the building.

In some aspects, the techniques described herein relate to a system, including a communications component that transmits the first information to at least one of an electric company or a customer of the electric company.

In some aspects, the techniques described herein relate to a system, including: a second electrical sensor for measuring an electrical property of a second power line to the building; a third analog-to-digital converter that processes an analog output of the second electrical sensor to generate a third digital signal, wherein the third digital signal is used by the metrology component of the electrical meter; and a fourth analog-to-digital converter that processes the analog output of the second electrical sensor to generate a fourth digital signal, wherein the fourth digital signal is not used by the metrology component of the electrical meter; wherein the first processing component processes the third digital signal and the second processing component processes the fourth digital signal.

In some aspects, the techniques described herein relate to a method, including: receiving power consumption data from a metrology component of an electrical meter connected to a building, wherein the power consumption data was computed using a first analog-to-digital converter; receiving an analog sensor signal from an electrical sensor; obtaining a digital sensor signal by processing the analog sensor signal with a second analog-to-digital converter; processing the digital sensor signal to determine first information corresponding to power consumption; determining an output using the first information and the power consumption data; and providing the output to a user.

In some aspects, the techniques described herein relate to a method, wherein the method is implemented by application processing component of an electrical meter.

In some aspects, the techniques described herein relate to a method, wherein the first analog-to-digital converter is part of the metrology component and the second analog-to-digital converter is external to the metrology component.

In some aspects, the techniques described herein relate to a method, wherein the power consumption data is computed using a first signal processing component of the metrology component and the first information is determined using a second signal processing component that is external to the metrology component.

In some aspects, the techniques described herein relate to a method, wherein the power consumption data is computed by processing the analog sensor signal with the first analog-to-digital converter.

In some aspects, the techniques described herein relate to a method, wherein the power consumption data is computed by processing a second analog sensor signal, from a second electrical sensor, with the first analog-to-digital converter.

In some aspects, the techniques described herein relate to a method, wherein the first information includes one or more of information about operation of an electrical grid connected to the electrical meter, information about a location of a power outage, identifying information about a first device in the building, information about a state change of a first device in the building, energy consumption of a first device in the building, or energy consumption of a second device in the building.

### BRIEF DESCRIPTION OF THE FIGURES

The invention and the following detailed description of certain embodiments thereof may be understood by reference to the following figures:

FIG. 1 is an example system for using an electrical meter to measure electric energy consumption of devices in a building where the electrical meter is connected to an electrical panel of the building;

FIG. 2 is an example electrical meter that may be used to measure electric energy consumption;

FIG. 3 is an example electrical meter with an application processing component to provide additional functionality;

FIG. 4 is an example electrical meter with an application processing component that receives and processes analog sensor signals;

FIG. 5 is an example electrical meter with a second set of sensors for an application processing component that receives and processes analog sensor signals;

FIG. 6 is a flowchart of operations of an example application implemented by an application processing component on an electrical meter using dual analog-to-digital converters (ADCs); and

FIG. 7 is a flowchart of operations of an example application implemented by an application processing component on an electrical meter that does not have access to information from a metrology component of the electrical meter.

### DETAILED DESCRIPTION

Electrical meters may measure electrical consumption of devices in a building using digital processing. The analog outputs of electrical sensors may be converted to digital signals, and the digital signals may be processed to determine an amount of electric energy consumption for billing purposes. The portion of an electrical meter that determines electric energy consumption may be referred to as a metrology component.

It is, generally, important that the metrology component of an electrical meter provide accurate information about electric energy consumption. Customers may be upset if they are overcharged for their electrical use, and electric companies may lose money if they undercharge their customers. Accordingly, the electrical meter and the metrology component may be designed for high accuracy.

It may be desired for an electrical meter to provide other functionality in addition to measuring electric energy consumption. For example, an electrical meter may be able to provide information about the electrical grid (e.g., a down power line) or information or services to the electrical customer (e.g., by using electrical disaggregation to determine information about individual devices in a house).

Having an electrical meter with such functionality provides numerous benefits to electrical providers and customers. Providing such features as part of an existing metrology component may require additional certification or recertification of the metrology component to ensure accuracy of the metrology component, and such certifications may be costly. Further, the existing processing (e.g., analog to digital conversion and associated signal processing) of the electrical meter may not be sufficient to support the desired additional functionality.

To enable an electrical meter to provide additional functionality without costly certification of a metrology component, dual analog-to-digital converters (ADCs) may be used. A first set of ADCs may be used by a metrology component to accurately compute electric energy consumption. A second set of ADCs may be used by an application component to provide additional functionality. The second set of ADCs may use a different configuration (e.g., sampling rate and/or bit depth) to provide a digital signal that provides greater capabilities for implementing other functionality. As will be appreciated, use of multiple sets of dual ADCs, in accordance with certain embodiments disclosed herein, eliminates and/or mitigates the impact on a metrology component from imparting additional features into a meter design. In other words, embodiments of the current disclosure provide for the modification of a meter design without affecting the metrology component, thereby eliminating and/or reducing the need to certify (or re-certify) a metrology component.

The techniques described herein may use any of the techniques described in U.S. non-Provisional patent application Ser. No. 14/707,665 (now issued as U.S. Pat. No. 9,443,195), filed May 8, 2015 (SAGE-0002-U01); U.S. non-Provisional patent application Ser. No. 16/054,535 (now issued as U.S. Pat. No. 10,750,252), filed Aug. 3, 2018 (SAGE-0005-U01); U.S. non-Provisional patent application Ser. No. 15/824,174 (now issued as U.S. Pat. No. 10,175,276), filed Nov. 28, 2017 (SAGE-0004-U01); U.S. non-Provisional patent application Ser. No. 16/179,567 (now issued as U.S. Pat. No. 10,878,343), filed Nov. 2, 2018 (SAGE-0006-U01); and U.S. non-Provisional patent application Ser. No. 16/858,897 (now issued as U.S. Pat. No. 11,536,747 and published as U.S. Pat. App. Publication No. 2021/0011056 A1), filed Apr. 27, 2020 (SAGE-0007-U01); each of which is incorporated by reference herein in their entirety.

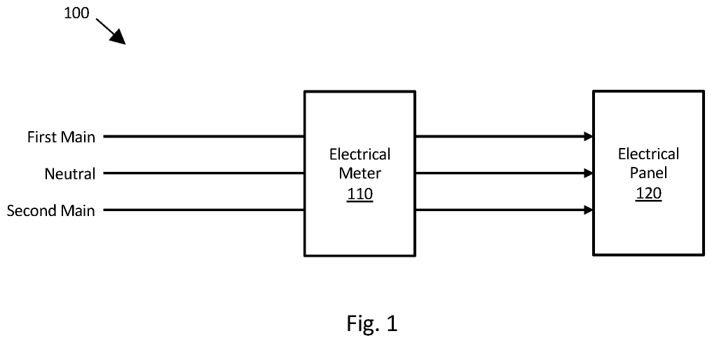

FIG. 1 is an example system 100 for using an electrical meter 110 to measure electric energy consumption of devices in a building where electrical meter 110 is connected to an electrical panel 120 of the building. As used herein, a building may include any group of devices that are receiving electricity regardless of whether those devices correspond to a residence, a business, and/or other entity; regardless of whether the devices are inside or outside of a structure; and regardless of whether a building has multiple electrical meters where a single electrical meter provides electricity to only some devices in the building.

In the example of FIG. 1, the electric company may be providing electrical power using a split phase or a single-phase three-wire system. For example, a first electrical main may provide 120 volts of electricity, and a second electrical main may provide 120 volts of electricity that is out of phase by 180 degrees with the first main. In some instances, a third wire may provide a neutral (which may or may not be accessible by the meter). The electrical customer may use a single main for some devices and may use both mains for devices that require 240 volts of electricity. The techniques described herein, however, are not limited to split phase or a single-phase three-wire system and may be used with any appropriate electrical distribution system, such as a single wire, two phase, or three phase electrical system. As used herein, the term electrical lines encompass any lines or wires used by an electric company to provide electric power to its customers. The term electric lines includes, but is not limited to, one or more of a first main, a second main, or a neutral.

Electrical meter 110 may have service line terminals to connect to service lines provided by the electric company (e.g., first main, second main, and neutral) and may have load terminals to connect to electrical panel 120. Electrical meter 110 may also have a ground terminal and any other terminals that may be used by an electrical meter. Electrical panel 120 may distribute power received via the load lines to multiple circuits in the building using any appropriate techniques.

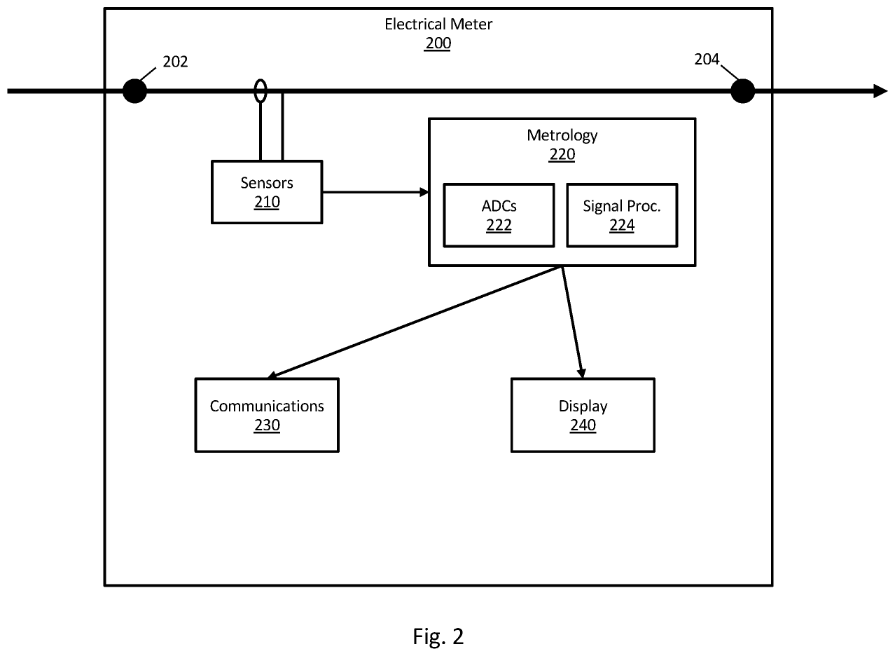

FIG. 2 is an example electrical meter 200 that may be used to measure electric energy consumption. In FIG. 2, line terminal 202 connects electrical meter 200 to a service line (e.g., first main, second main, or neutral) and load terminal 204 connects electrical meter 200 to a load line (e.g., first main, second main, or neutral). Electrical meter 200 may have multiple sets of terminals for multiple service and load lines, but for clarity of presentation only a single pair of terminals is shown. Electrical meter 200 may also include switches or cutoffs to allow the electric company to disconnect the service lines from the load lines.

Electrical meter 200 may have sensors 210 for measuring electrical properties of the electric lines (e.g., first main, second main, or neutral). Any appropriate sensors may be used, such as a current sensor and/or a voltage sensor. The sensors may be implemented using any appropriate technology, such as a current shunt, a current transformer, a Hall effect sensor, and/or a Rogowski coil. Each sensor may output an analog signal that is proportional to the electrical property being measured. For example, a sensor may output an analog signal corresponding to one or more of a current of a main, a voltage between a main and a neutral, or a voltage between two mains.

Metrology component 220 may process the analog signals received from sensors 210 and perform any appropriate computations, such as determining power quality or determining an amount of electric energy consumption over a period of time. As used herein, a metrology component of the electrical meter includes the portions of the electrical meter that are responsible for computing energy consumption values by processing sensor values (or computing intermediate values that may be used to compute energy consumption values).

Metrology component 220 may include one or more analog-to-digital converters, such as ADCs 222. ADCs 222 may be implemented using any appropriate techniques, such as a delta-sigma ADC. In some implementations, metrology component 220 may have an ADC for each sensor. For example, metrology component 220 may have a first ADC for a current sensor of a first main, a second ADC for a voltage sensor of the first main, a third ADC for a current sensor of a second main, and so forth. Each ADC may output a digital signal that is proportional to the electrical property being measured (e.g., current or voltage).

In some implementations, digital sensor signals may be adapted to different frequency bands or ranges. For example, a first digital voltage sensor signal may be adapted to measure high frequency content, and a second digital voltage sensor signal may be adapted to measure low frequency content. Similarly, a first digital current sensor signal may be adapted to measure high frequency content, and a second digital current sensor signal may be adapted to measure low frequency content. Any number of digital sensor signals may be used that are adapted to measure content at different frequency bands or ranges.

Metrology component 220 may include a signal processing component 224 that processes the digital signals output by ADCs 222. Signal processing component 224 may be implemented using any appropriate techniques, such as solid-state electronics, microprocessors, integrated circuits, micro-controller units, and/or processors and software. In some implementations, signal processing component 224 may compute instantaneous electric power consumption and use accumulators and/or integrators to determine an amount of electric energy consumption over a period of time. Signal processing component 224 may also perform other operations, such as tamper detection, power quality, and/or power factor.

In some implementations, ADCs 222 and signal processing component 224 may be implemented as a single component, such as a chip that performs the operations of both ADCs 222 and signal processing component 224.

Electrical meter 200 may include a communications component 230 to transmit information to the electric company, the customer, or other entities. Communications component 230 may use any appropriate communications techniques, such as telemetry, infrared communications, low-power radio, Bluetooth, Wi-Fi, and/or cellular communications.

Electrical meter 200 may include a display component 240 for presenting information at the meter. Display component 240 may include any appropriate display, such as LEDs, OLEDs, seven-segment displays, or liquid crystal displays. Display component 240 may present any appropriate information, such as a rate of electric power consumption.

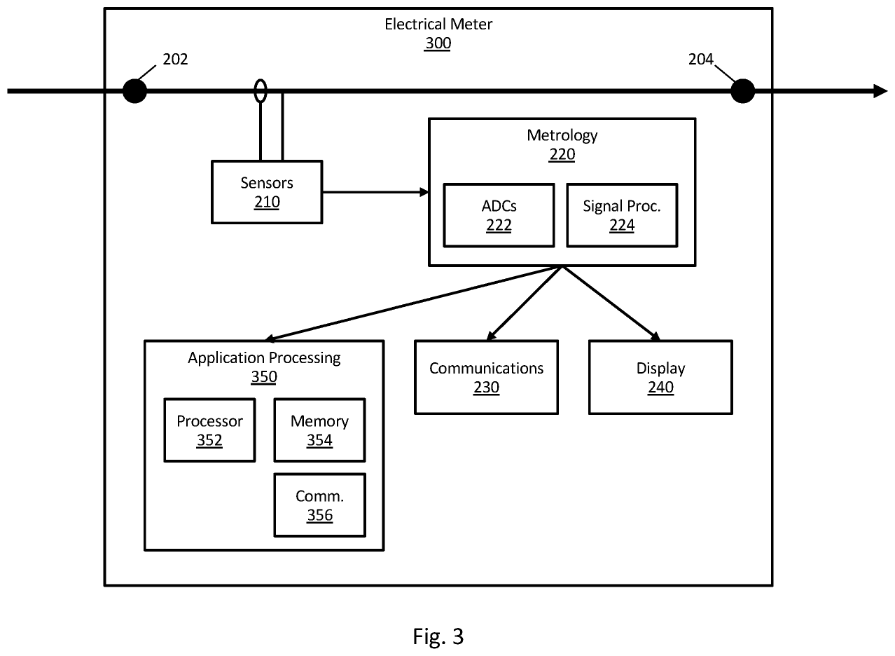

FIG. 3 is an example electrical meter 300 with an application processing component 350 to provide additional functionality.

Application processing component 350 may be configured to receive data from metrology component 220 and use that data to provide additional functionality or benefits. Application processing component 350 may provide any appropriate functionality and/or benefits, and the functionality may be provided to the electric company, the customer of the electrical company, and/or to third parties (e.g., the manufacturers of devices that consume electricity).

Application processing component 350 may provide any appropriate functionality, such as the following: detection of electrical meter tampering (e.g., by customers attempting to reduce their electrical bill), detection relating to the operation of the electrical grid (e.g., irregularities in voltage, frequency, or power factor), detection and localization of power outages, detection of electrical faults in the customer's house (e.g., a floating neutral), identifying devices in a customer's house and detecting state changes of those devices (e.g., using electrical disaggregation techniques), functionality relating to the determination of device state changes in the customer's house (e.g., that a device is not functioning correctly and needs repair, identification of devices consuming large amounts of electricity, or alerts to users (such as when a refrigerator door is left open)).

Application processing component 350 may receive any appropriate data or information from metrology component 220. For example, application processing component 350 may receive any of the following: sensor measurements, rate of power consumption information, or any other computations determined from sensor measurements.

In some implementations, application processing component 350 may not have any access to the analog signals output by sensors 210, and the only source of data may be the data provided by metrology component 220.

Application processing component 350 may be implemented using any appropriate techniques. In some implementations, application processing component 350 may include a processor 352, such as a central processing unit, or may include multiple processors. Application processing component 350 may include memory 354, which may include any appropriate volatile and or non-volatile memory. Memory 354 may store any appropriate software to be executed by processor 352, such as an operating system (e.g., Linux) and other software to implement any of the functionality, features, or applications described herein.

Application processing component 350 may include communications component 356 that may be implemented using any appropriate communications techniques, such as those described for communications component 230. In some implementations, application processing component 350 may not have access to communications component 230 and may thus need communications component 356 for transmitting and receiving data. In some implementations, the functionality of communications component 230 may be insufficient (e.g., too low bandwidth) and communications component 356 may provide functionality to improve the operations of application processing component 350.

In some implementations, applications (“apps”) or software may be installed on application processing component 350. For example, the electric company may install an application for its own use, such as for performing diagnostics of the electrical grid. For another example, a customer may install applications (or the electrical company may install applications on behalf of the customer) to provide the customer with additional functionality, such as any of the functionality described herein. In some implementations, an application store (or app store) may be available to facilitate the installation of applications on application processing component 350.

In some instances, an application for execution on an application processing component may require data that metrology component 220 is not able to provide. For example, ADCs 222 of metrology component 220 may sample the analog signal using parameters, such as a first sampling rate and a first bit depth. These parameters may be sufficient for computing electric energy consumption but may be insufficient for other applications. For example, other applications may require that analog sensor signals be sampled with a higher sampling rate and/or a higher bit depth.

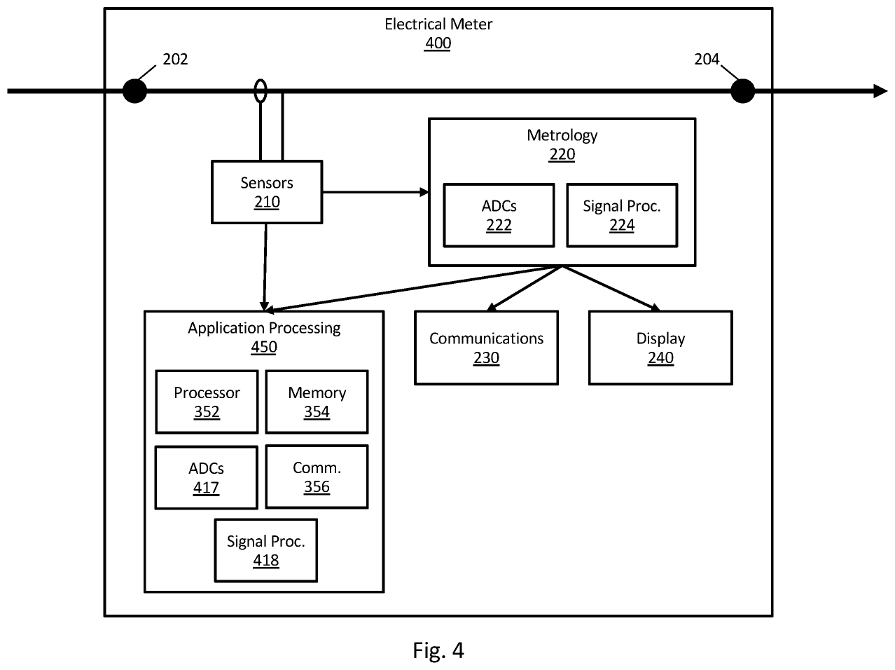

FIG. 4 is an example electrical meter 400 with an application processing component 450 that receives and processes analog sensor signals. Application processing component 450 may include any of the functionality described herein for application processing component 350.

Application processing component 450 may include ADCs 417 that process the analog sensor signals to compute a digital signal. For example, application processing component 450 may have a first ADC for the current sensor of a first main, a second ADC for the voltage sensor of the first main, a third ADC for the current sensor of a second main, and so forth. Each ADC may output a digital signal that is proportional to the electrical property being measured (e.g., current or voltage). ADCs 417 may have different parameters than ADCs 222. For example, ADCs 417 may have a higher sampling rate and/or bit depth than ADCs 222.

Application processing component 450 may include a signal processing component 418 that processes the digital signals output by ADCs 417. Signal processing component 418 may be implemented using any appropriate techniques, such as described herein for signal processing component 224. In some implementations, signal processing component 418 may be configured to process the digital signals output by ADCs 417 (e.g., greater capacities for handling larger sampling rates or bit depths). In some implementations, the operations of signal processing component 418 may be performed by processor 352, and signal processing component 418 may denote a subset of the operations performed by processor 352. Operations of signal processing component 418 may include spectral analysis to provide information about harmonics of the current and voltage measurements and/or time-domain analysis of current and voltage measurements. Signal processing component 418 may be able to process signals at higher frequencies (as compared to processing of a metrology component) to support additional capabilities and features.

In some implementations, application processing component 450 may also receive data from metrology component 220, such as any of the data described herein. In some implementations, application processing component 450 may not have access to any data from metrology component 220. For example, manufacturing limitations may prevent connections between metrology component 220 and an application processing component.

In some implementations, application processing component 450 may have access to voltage sensor measurements from sensors 210 and not current sensor measurements from sensors 210 (or vice versa). In such instances, sensors 210 may be split into separate sensors, e.g., (i) first sensors that are accessible by metrology component 220 and application processing component 450 and (ii) second sensors that are accessible by metrology component 220 but not accessible by application processing component 450. For example, allowing the application processing component 450 to access the analog current sensor reading may cause additional certification requirements (to ensure that the power consumption measurements of the electrical meter are not affected), and it may be desired to avoid additional certification to reduce costs of production or prevent delays. In such instances, application processing component 450 may (a) process voltage sensor measurements from sensors 210 and not process any current measurements or (b) process voltage sensor measurements from sensors 210 and receive current sensor measurements via metrology component 220.

In some implementations, application processing component 450 may have access to or may be configured to use communications component 230 or display component 240. For example, application processing component 450 may use communications component 230 for communicating data to the electric company, a customer, and/or third parties. One benefit of the application processing component 450 having access to and/or use of the communications component 230 is the ability for a manager/owner/operator of a meter 400 to send data to and/or receive data from the application processing component 450 without the need for a human to be physically present at the side of the meter 400. For example, one non-limiting use case of a meter 400 having an application processing component 450 with access to and/or use of a communications component 230 includes an electric company with hundreds, thousands, hundreds-of-thousands, and/or millions of customers, where a plurality of the customers have meters, in accordance with embodiments disclosed herein, installed at their residences. In such a scenario, the electric company could push a software update to the application processing components without having to send an employees/technicians to the location of each meter. Additionally, the ability to remotely update the application processing component 450 eliminates and/or reduces the need for a technician to physically interact with a meter and/or its corresponding lines, which reduces the likelihood of the technician accidentally electrocuting themself.

Application processing component 450 may also use display component 240 to present information relating to functionality of application processing component 450 (e.g., diagnostic information) or to applications implemented by application processing component 450.

In some instances, sensors 210 that are used by metrology component 220 may not be available to an application processing component. For example, manufacturing limitations may prevent connections between sensors 210 and an application processing component.

In some instances, an application that is desired to run on an electrical meter may be improved with data that sensors 210 are not able to provide. For example, an application may require sensor measurements with greater accuracy than provided by sensors 210. For another example, an application may require a different type of sensor than provided by sensors 210 (e.g., where sensors 210 combine readings for two mains into a single value but a separate value for each main is needed).

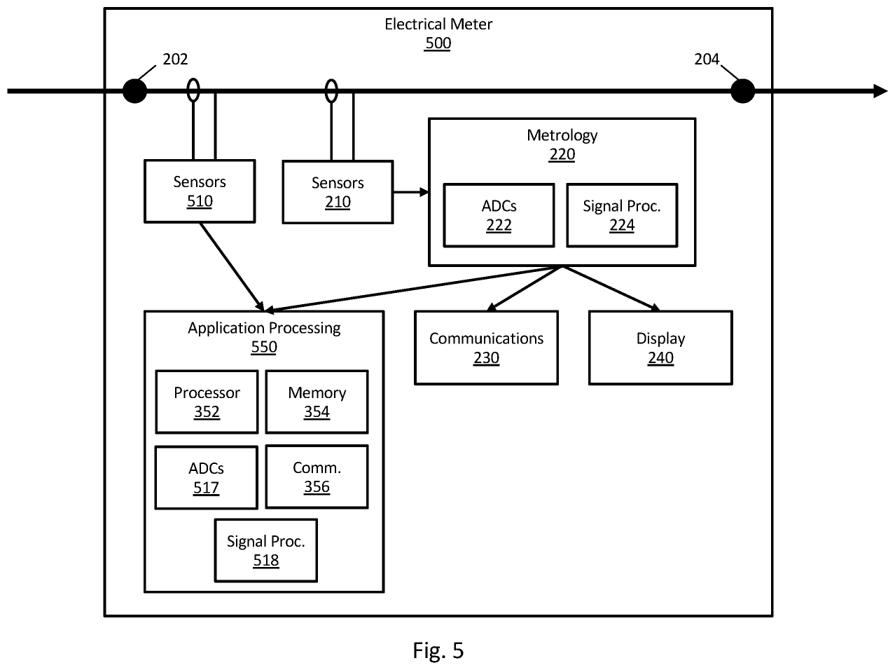

FIG. 5 is an example electrical meter 500 with a second set of sensors for an application processing component 550 that receives and processes analog sensor signals. Application processing component 550 may include any of the functionality described herein for application processing component 350 or application processing component 450.

Sensors 510 may include any appropriate sensors, such as any of the sensors described herein for sensors 210. Sensors 510 may provide different types of information than sensors 210 and/or may provide greater accuracy than sensors 210. Sensors 510 may allow for greater isolation between the operation of metrology component 220 and application processing component 550. In some implementations, the output of sensors 510 may not be accessible to metrology component 220 and the output of sensors 210 may not be accessible to application processing component 550.

Application processing component 550 may include ADCs 517 and/or signal processing component 518 that are adapted to the signals provided by sensors 510. For example, where sensors 510 provide signals with greater accuracy, ADCs 517 may provide additional functionality, such as higher accuracy, higher sampling rate, or higher bit depth. Signal processing component 518 may also provide additional processing adapted to sensors 510 and/or ADCs 517.

In some implementations, sensors 510 may include voltage sensors and not current sensors (or vice versa). As described above, accessing a current sensor reading may cause additional certification requirements. In such instances, application processing component 550 may (a) process voltage sensor measurements from sensors 510 and not process any current measurements or (b) process voltage sensor measurements from sensors 510 and receive current sensor measurements via metrology component 220.

In some implementations, application processing component 550 may receive data from metrology component 220 or may have access to communications component 230 and/or display component 240. For example, application processing component 550 may receive power consumption information computed by metrology component 220 or may receive sensor signals from metrology component 220. In some implementations, application processing component 550 may not have any access to data from metrology component 220 and/or may not have access to communications component 230 or display component 240.

An application processing component on an electrical meter may implement a variety of applications. In some instances, the applications may use data that is generated from more than one set of ADCs (e.g., dual ADCs) and/or more than one set of sensors.

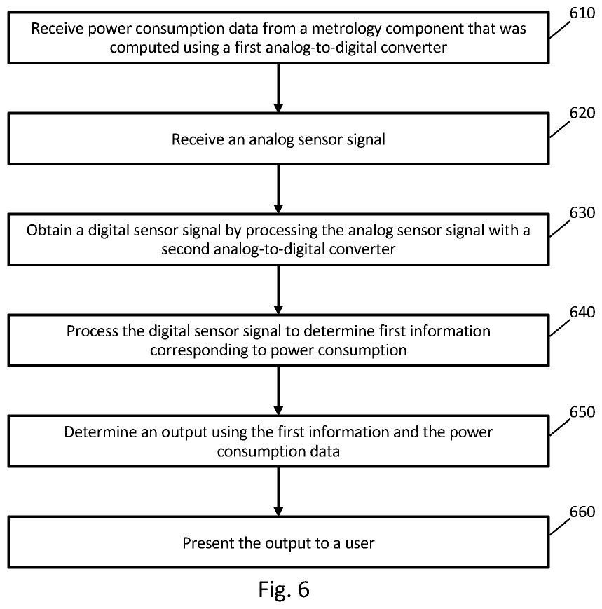

FIG. 6 is a flowchart of operations of an example application implemented by an application processing component on an electrical meter using dual ADCs. In FIG. 6 and other flowcharts herein, the ordering of the steps is exemplary and other orders are possible, not all steps are required, and, in some implementations, some steps may be omitted, or other steps may be added. The process of the flowcharts may be implemented, for example, by any of the computers or systems described herein.

At step 610, energy or power consumption data is received from a metrology component of the electrical meter. The power consumption data may correspond to a live stream of power consumption information, such as a stream of power consumption values at a rate of one per second where each power consumption value corresponds to an amount of power consumed over a one second interval (e.g., an average amount of power consumed over the interval).

The power consumption data may be computed by processing an analog sensor signal received from a sensor, such as any of the sensors described herein. The analog sensor signal may be processed with a first ADC, and the first ADC may be part of a metrology component of the electrical meter. The power consumption data may also be computed using a first signal processing component of the metrology component. The first signal processing component may process the output of the first ADC to compute the power consumption data.

At step 620, an analog sensor signal is received. In some implementations, multiple analog signals may be received from multiple sensors. The analog sensor signal or signals may correspond to any sensors used by an electrical meter, such as any of the sensors described herein. The analog signal may be the same analog sensor signal processed by the metrology component or may be a different analog sensor signal (e.g., from a different sensor).

At step 630, a digital sensor signal is obtained by processing the analog sensor signal with a second ADC that is different from the first ADC. The second ADC may be part of the application processing component. Any appropriate ADC may be used, such as any of the ADCs described herein. Where more than one analog sensor signal is received, more than one ADC may be used to convert the analog sensor signals to digital sensor signals. The output of second ADC is not used by a metrology component of the electrical meter and the second ADC is separate from any ADCs used by a metrology component of the electrical meter. The second ADC may be external to the metrology component of the electrical meter.

The first and second ADCs may perform different types of analog-to-digital conversion or may be configured with different processing parameters. For example, the first and second ADCs may have different sampling rates and/or different bit depths. In some implementations, the first and second ADCs may process the same analog signal received from the same sensor. In some implementations, the first and second ADCs may process different analog sensor signals received from different sensors.

At step 640, the digital signal is processed to determine first information corresponding to power consumption. For example, the first information may correspond to the operation of the electrical grid, power consumption of the customer receiving service via the electrical meter, and/or power consumption of individual devices. In some implementations, step 640 may be performed by a second signal processing component that is part of the application processing component and different from the first signal processing component. In some implementations, step 640 may be performed by a processor (e.g., a CPU). In some implementations, step 640 may be performed using both a second signal processing component and a processor.

In some implementations, the first information may include first device information about a first device that receives power via the electrical meter. The first device may be any type of device, such as an appliance, a light, a computer, and so forth. The first device information may include any appropriate information about the device, such as any of the device information disclosed in the patents and patent publications incorporated by reference or any combination of the following. The first device information may include identifying information, such as a type of device (e.g., the device is a dishwasher), a manufacturer of a device (e.g., a Bosch dishwasher), or a model of a device (e.g., a Bosch 500 series dishwasher). The first device information may include a state change of a device (e.g., the device turned on, the device turned off, or the dishwasher changed from a washing mode to a rinsing mode). The first device information may include an amount of electric power being consumed by the device (e.g., the dishwasher is consuming 100 watts). The first device information may include information about the health of a device (e.g., the device is operating normally or a part of a device is wearing out and needs replacement).

In some implementations, the digital signal may be processed to also determine second information corresponding to power consumption. The second information may include any of the examples for the first information described above. In some implementations, the second information may include second device information about a second device that receives power via the electrical meter. The second device information may include any of the information described above for the first device information.

At step 650, an output is determined using the first information and the power consumption data. Because the first information and the power consumption data are computed using different ADCs (and possibly different sensors), the first information and the power consumption data may not be entirely in agreement with each other. For example, the first information may indicate that the customer consumed 2.1 kilowatt-hours over a time interval and the power consumption data may indicate that the customer consumed 2.2 kilowatt-hours over the same time interval. In some implementations, the output may resolve any differences between the first value and the power consumption data, such as by modifying the first information using the power consumption data. In some implementations, the output may be a combination of the first information and the power consumption data (e.g., the output may include (i) a state change of a first device that is part of the first information and (ii) the total amount of energy consumed over a time period that is part of the power consumption data).

In some implementations, the first digital sensor signal may be used to determine energy consumption information for multiple devices in the house. For example, the first digital sensor signal may be process to compute (i) energy consumption of a first device, (ii) energy consumption of a second device, and (iii) energy consumption of all other devices receiving electricity via the electrical meter (collectively, the three may be referred to as “device energy values”). The power consumption data received from the metrology component may indicate a total energy consumption value for all devices receiving electricity via the electrical meter. The sum of the device energy values computed from the first digital sensor signal should be equal to total energy consumption value received from the metrology component. In practice, they may not be precisely equal due to differences in the processing paths (e.g., different sensors and/or ADCs). At step 650, the output may include modified versions of the device energy values so that their sum is equal to the total energy consumption value. For example, each of the device energy consumption values may be normalized by dividing by the sum of the device energy consumption values and multiplying by the total energy consumption value.

At step 660, the output may be presented to a user. The output may be used for any appropriate purpose. For example, the output may be provided to the electric company, the customer, or a third party.

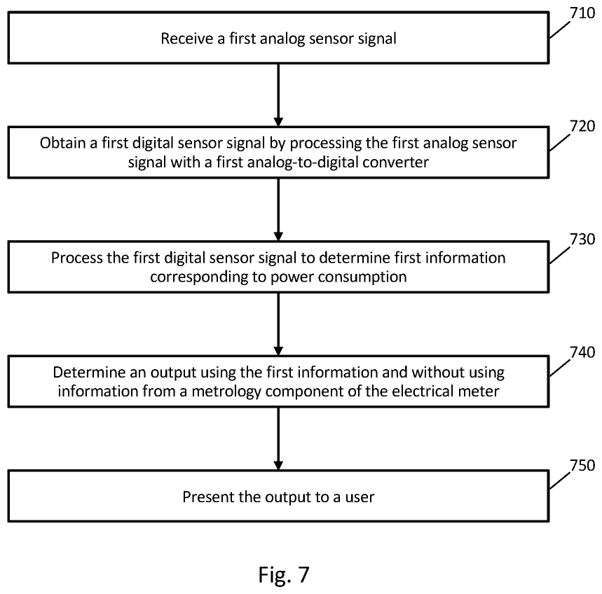

FIG. 7 is a flowchart of operations of an example application implemented by an application processing component on an electrical meter that does not have access to information from a metrology component of the electrical meter.

At step 710, an analog sensor signal is received. Step 710 may be implemented using any of the techniques described above for step 620.

At step 720, a digital sensor signal is obtained by processing the analog sensor signal with a second ADC, where the output of the second ADC is not used by a metrology component. Step 720 may be implemented using any of the techniques described above for step 630.

At step 730, the digital signal is processed to determine first information corresponding to power consumption. Step 730 may be implemented using any of the techniques described above for step 640.

At step 740, an output is determined using the first information. The output may be determined using any of the techniques described above for step 650 except that no data or information from the metrology component is used since the application processing component does not have access to any data or information of the metrology component.

At step 750, the output may be presented to a user. The output may be used for any appropriate purpose. For example, the output may be provided to the electric company, the customer, or a third party.

In some implementations, the techniques described herein may be implemented as described in any combination of the following clauses.

Clause 1. An electrical meter, comprising: an electrical sensor for measuring an electrical property of a power line to a building; a metrology component; a first analog-to-digital converter that processes an analog output of the electrical sensor to generate a first digital signal, wherein the first digital signal has a first sampling rate and the first digital signal is used by the metrology component of the electrical meter; a first processing component of the metrology component that processes the first digital signal to determine an energy consumption value for devices of the building; a second analog-to-digital converter that processes the analog output of the electrical sensor to generate a second digital signal, wherein the second digital signal has a second sampling rate that is different from the first sampling rate and the second digital signal is not used by the metrology component of the electrical meter; and a second processing component that processes the second digital signal to determine first information corresponding to power consumption.

Clause 2. The electrical meter of clause 1, wherein the first processing component is a first signal processing component.

Clause 3. The electrical meter of clause 1, wherein the electrical sensor is a current sensor.

Clause 4. The electrical meter of clause 1, wherein the first analog-to-digital converter has a first bit depth and the second analog-to-digital converter has a second bit depth that is different from the first bit depth.

Clause 5. The electrical meter of clause 1, wherein the first analog-to-digital converter is part of the metrology component and the second analog-to-digital converter is external to the metrology component.

Clause 6. The electrical meter of clause 1, wherein the first information corresponding to power consumption comprises information about operation of an electrical grid connected to the electrical meter.

Clause 7. The electrical meter of clause 1, wherein the first information corresponding to power consumption comprises information about a location of a power outage.

Clause 8. The electrical meter of clause 1, wherein the first information corresponding to power consumption comprises identifying information about a first device in the building.

Clause 9. A system comprising: an electrical sensor for measuring an electrical property of a power line to a building; a metrology component; a first analog-to-digital converter that processes an analog output of the electrical sensor to generate a first digital signal, wherein the first digital signal has a first sampling rate and the first digital signal is used by the metrology component of an electrical meter; a first processing component of the metrology component that processes the first digital signal to determine an energy consumption value for devices of the building; a second analog-to-digital converter that processes the analog output of the electrical sensor to generate a second digital signal, wherein the second digital signal has a second sampling rate that is different from the first sampling rate and the second digital signal is not used by the metrology component of the electrical meter; and a second processing component that processes the second digital signal to determine first information corresponding to power consumption.

Clause 10. The system of clause 9, wherein the first information corresponding to power consumption comprises information about a state change of a first device in the building.

Clause 11. The system of clause 9, wherein the first information corresponding to power consumption comprises (i) energy consumption of a first device in the building and (ii) energy consumption of a second device in the building.

Clause 12. The system of clause 9, comprising a communications component that transmits the first information to at least one of an electric company or a customer of the electric company.

Clause 13. The system of clause 9, comprising: a second electrical sensor for measuring an electrical property of a second power line to the building; a third analog-to-digital converter that processes an analog output of the second electrical sensor to generate a third digital signal, wherein the third digital signal is used by the metrology component of the electrical meter; and a fourth analog-to-digital converter that processes the analog output of the second electrical sensor to generate a fourth digital signal, wherein the fourth digital signal is not used by the metrology component of the electrical meter; wherein the first processing component processes the third digital signal and the second processing component processes the fourth digital signal.

Clause 14. A method, comprising: receiving power consumption data from a metrology component of an electrical meter connected to a building, wherein the power consumption data was computed using a first analog-to-digital converter; receiving an analog sensor signal from an electrical sensor; obtaining a digital sensor signal by processing the analog sensor signal with a second analog-to-digital converter; processing the digital sensor signal to determine first information corresponding to power consumption; determining an output using the first information and the power consumption data; and providing the output to a user.

Clause 15. The method of clause 14, wherein the method is implemented by application processing component of an electrical meter.

Clause 16. The method of clause 14, wherein the first analog-to-digital converter is part of the metrology component and the second analog-to-digital converter is external to the metrology component.

Clause 17. The method of clause 14, wherein the power consumption data is computed using a first signal processing component of the metrology component and the first information is determined using a second signal processing component that is external to the metrology component.

Clause 18. The method of clause 14, wherein the power consumption data is computed by processing the analog sensor signal with the first analog-to-digital converter.

Clause 19. The method of clause 14, wherein the power consumption data is computed by processing a second analog sensor signal, from a second electrical sensor, with the first analog-to-digital converter.

Clause 20. The method of clause 14, wherein the first information comprises one or more of information about operation of an electrical grid connected to the electrical meter, information about a location of a power outage, identifying information about a first device in the building, information about a state change of a first device in the building, energy consumption of a first device in the building, or energy consumption of a second device in the building.

While only a few embodiments of the present invention have been shown and described, it will be obvious to those skilled in the art that many changes and modifications may be made thereunto without departing from the spirit and scope of the present disclosure as described in the following claims. All patent applications and patents, both foreign and domestic, and all other publications referenced herein are incorporated herein in their entireties to the full extent permitted by law.

The methods and systems described herein may be deployed in part or in whole through a machine that executes computer software, program codes, and/or instructions on a processor. The processor may be part of a server, cloud server, client, network infrastructure, mobile computing platform, stationary computing platform, and/or other computing platform. A processor may be any kind of computational or processing device capable of executing program instructions, codes, binary instructions and the like. The processor may be or include a signal processor, digital processor, embedded processor, microprocessor or any variant such as a co-processor (math co-processor, graphic co-processor, communication co-processor and the like) and the like that may directly or indirectly facilitate execution of program code or program instructions stored thereon. In addition, the processor may enable execution of multiple programs, threads, and codes. The threads may be executed simultaneously to enhance the performance of the processor and to facilitate simultaneous operations of the application. By way of implementation, methods, program codes, program instructions and the like described herein may be implemented in one or more thread. The thread may spawn other threads that may have assigned priorities associated with them; the processor may execute these threads based on priority or any other order based on instructions provided in the program code. The processor may include memory that stores methods, codes, instructions and programs as described herein and elsewhere. The processor may access a storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of a CD-ROM, DVD, memory, hard disk, flash drive, RAM, ROM, cache and the like.

A processor may include one or more cores that may enhance speed and performance of a multiprocessor. In embodiments, the process may be a dual core processor, quad core processors, other chip-level multiprocessor and the like that combine two or more independent cores (called a die).

The methods and systems described herein may be deployed in part or in whole through a machine that executes computer software on a server, cloud server, client, firewall, gateway, hub, router, or other such computer and/or networking hardware. The software program may be associated with a server that may include a file server, print server, domain server, internet server, intranet server and other variants such as secondary server, host server, distributed server and the like. The server may include one or more of memories, processors, computer readable media, storage media, ports (physical and virtual), communication devices, and interfaces capable of accessing other servers, clients, machines, and devices through a wired or a wireless medium, and the like. The methods, programs or codes as described herein and elsewhere may be executed by the server. In addition, other devices required for execution of methods as described in this application may be considered as a part of the infrastructure associated with the server.

The server may provide an interface to other devices including, without limitation, clients, other servers, printers, database servers, print servers, file servers, communication servers, distributed servers and the like. Additionally, this coupling and/or connection may facilitate remote execution of program across the network. The networking of some or all of these devices may facilitate parallel processing of a program or method at one or more location without deviating from the scope of the disclosure. In addition, any of the devices attached to the server through an interface may include at least one storage medium capable of storing methods, programs, code and/or instructions. A central repository may provide program instructions to be executed on different devices. In this implementation, the remote repository may act as a storage medium for program code, instructions, and programs.

The software program may be associated with a client that may include a file client, print client, domain client, internet client, intranet client and other variants such as secondary client, host client, distributed client and the like. The client may include one or more of memories, processors, computer readable media, storage media, ports (physical and virtual), communication devices, and interfaces capable of accessing other clients, servers, machines, and devices through a wired or a wireless medium, and the like. The methods, programs or codes as described herein and elsewhere may be executed by the client. In addition, other devices required for execution of methods as described in this application may be considered as a part of the infrastructure associated with the client.

The client may provide an interface to other devices including, without limitation, servers, other clients, printers, database servers, print servers, file servers, communication servers, distributed servers and the like. Additionally, this coupling and/or connection may facilitate remote execution of program across the network. The networking of some or all of these devices may facilitate parallel processing of a program or method at one or more location without deviating from the scope of the disclosure. In addition, any of the devices attached to the client through an interface may include at least one storage medium capable of storing methods, programs, applications, code and/or instructions. A central repository may provide program instructions to be executed on different devices. In this implementation, the remote repository may act as a storage medium for program code, instructions, and programs.

The methods and systems described herein may be deployed in part or in whole through network infrastructures. The network infrastructure may include elements such as computing devices, servers, routers, hubs, firewalls, clients, personal computers, communication devices, routing devices and other active and passive devices, modules and/or components as known in the art. The computing and/or non-computing device(s) associated with the network infrastructure may include, apart from other components, a storage medium such as flash memory, buffer, stack, RAM, ROM and the like. The processes, methods, program codes, instructions described herein and elsewhere may be executed by one or more of the network infrastructural elements.

The methods, program codes, and instructions described herein and elsewhere may be implemented on a cellular network having multiple cells. The cellular network may either be frequency division multiple access (FDMA) network or code division multiple access (CDMA) network. The cellular network may include mobile devices, cell sites, base stations, repeaters, antennas, towers, and the like. The cell network may be a GSM, GPRS, 3G, EVDO, mesh, and/or other networks types.

The methods, programs codes, and instructions described herein and elsewhere may be implemented on or through mobile devices. The mobile devices may include navigation devices, cell phones, mobile phones, mobile personal digital assistants, laptops, palmtops, netbooks, pagers, electronic books readers, music players and the like. These devices may include, apart from other components, a storage medium such as a flash memory, buffer, RAM, ROM and one or more computing devices. The computing devices associated with mobile devices may be enabled to execute program codes, methods, and instructions stored thereon. Alternatively, the mobile devices may be configured to execute instructions in collaboration with other devices. The mobile devices may communicate with base stations interfaced with servers and configured to execute program codes. The mobile devices may communicate on a peer-to-peer network, mesh network, or other communications network. The program code may be stored on the storage medium associated with the server and executed by a computing device embedded within the server. The base station may include a computing device and a storage medium. The storage device may store program codes and instructions executed by the computing devices associated with the base station.

The computer software, program codes, and/or instructions may be stored and/or accessed on machine readable media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g. USB sticks or keys), floppy disks, magnetic tape, paper tape, punch cards, standalone RAM disks, Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, and the like.

The methods and systems described herein may transform physical and/or or intangible items from one state to another. The methods and systems described herein may also transform data representing physical and/or intangible items from one state to another, such as from usage data to a normalized usage dataset.

The elements described and depicted herein, including in flow charts and block diagrams throughout the figures, imply logical boundaries between the elements. However, according to software or hardware engineering practices, the depicted elements and the functions thereof may be implemented on machines through computer executable media having a processor capable of executing program instructions stored thereon as a monolithic software structure, as standalone software modules, or as modules that employ external routines, code, services, and so forth, or any combination of these, and all such implementations may be within the scope of the present disclosure. Examples of such machines may include, but may not be limited to, personal digital assistants, laptops, personal computers, mobile phones, other handheld computing devices, medical equipment, wired or wireless communication devices, transducers, chips, calculators, satellites, tablet PCs, electronic books, gadgets, electronic devices, devices having artificial intelligence, computing devices, networking equipment, servers, routers and the like. Furthermore, the elements depicted in the flow chart and block diagrams and/or any other logical component may be implemented on a machine capable of executing program instructions. Thus, while the foregoing drawings and descriptions set forth functional aspects of the disclosed systems, no particular arrangement of software for implementing these functional aspects should be inferred from these descriptions unless explicitly stated or otherwise clear from the context. Similarly, it will be appreciated that the various steps identified and described above may be varied, and that the order of steps may be adapted to particular applications of the techniques disclosed herein. All such variations and modifications are intended to fall within the scope of this disclosure. As such, the depiction and/or description of an order for various steps should not be understood to require a particular order of execution for those steps, unless required by a particular application, or explicitly stated or otherwise clear from the context.

The methods and/or processes described above, and steps thereof, may be realized in hardware, software or any combination of hardware and software suitable for a particular application. The hardware may include a general-purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and software, or any other machine capable of executing program instructions.

Thus, in one aspect, each method described above and combinations thereof may be embodied in computer executable code that, when executing on one or more computing devices, performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

All documents referenced herein are hereby incorporated by reference.

1. An electrical meter, comprising:
an electrical sensor for measuring an electrical property of a power line to a building;
a metrology component;
a first analog-to-digital converter that processes an analog output of the electrical sensor to generate a first digital signal, wherein the first digital signal has a first sampling rate and the first digital signal is used by the metrology component of the electrical meter;
a first processing component of the metrology component that processes the first digital signal to determine an energy consumption value for devices of the building;
a second analog-to-digital converter that processes the analog output of the electrical sensor to generate a second digital signal, wherein the second digital signal has a second sampling rate that is different from the first sampling rate and the second digital signal is not used by the metrology component of the electrical meter; and
a second processing component that processes the second digital signal to determine first information corresponding to power consumption.

2. The electrical meter of claim 1, wherein the first processing component is a first signal processing component.

3. The electrical meter of claim 1, wherein the electrical sensor is a current sensor.

4. The electrical meter of claim 1, wherein the first analog-to-digital converter has a first bit depth and the second analog-to-digital converter has a second bit depth that is different from the first bit depth.

5. The electrical meter of claim 1, wherein the first analog-to-digital converter is part of the metrology component and the second analog-to-digital converter is external to the metrology component.

6. The electrical meter of claim 1, wherein the first information corresponding to power consumption comprises information about operation of an electrical grid connected to the electrical meter.

7. The electrical meter of claim 1, wherein the first information corresponding to power consumption comprises information about a location of a power outage.

8. The electrical meter of claim 1, wherein the first information corresponding to power consumption comprises identifying information about a first device in the building.

9. A system comprising:
an electrical sensor for measuring an electrical property of a power line to a building;
a metrology component;
a first analog-to-digital converter that processes an analog output of the electrical sensor to generate a first digital signal, wherein the first digital signal has a first sampling rate and the first digital signal is used by the metrology component of an electrical meter;
a first processing component of the metrology component that processes the first digital signal to determine an energy consumption value for devices of the building;
a second analog-to-digital converter that processes the analog output of the electrical sensor to generate a second digital signal, wherein the second digital signal has a second sampling rate that is different from the first sampling rate and the second digital signal is not used by the metrology component of the electrical meter; and
a second processing component that processes the second digital signal to determine first information corresponding to power consumption.

10. The system of claim 9, wherein the first information corresponding to power consumption comprises information about a state change of a first device in the building.

11. The system of claim 9, wherein the first information corresponding to power consumption comprises (i) energy consumption of a first device in the building and (ii) energy consumption of a second device in the building.

12. The system of claim 9, comprising a communications component that transmits the first information to at least one of an electric company or a customer of the electric company.

13. The system of claim 9, comprising:
a second electrical sensor for measuring an electrical property of a second power line to the building;
a third analog-to-digital converter that processes an analog output of the second electrical sensor to generate a third digital signal, wherein the third digital signal is used by the metrology component of the electrical meter; and
a fourth analog-to-digital converter that processes the analog output of the second electrical sensor to generate a fourth digital signal, wherein the fourth digital signal is not used by the metrology component of the electrical meter;
wherein the first processing component processes the third digital signal and the second processing component processes the fourth digital signal.

14. A method, comprising:
receiving power consumption data from a metrology component of an electrical meter connected to a building, wherein the power consumption data was computed using a first analog-to-digital converter;
receiving an analog sensor signal from an electrical sensor;
obtaining a digital sensor signal by processing the analog sensor signal with a second analog-to-digital converter;
processing the digital sensor signal to determine first information corresponding to power consumption;
determining an output using the first information and the power consumption data; and
providing the output to a user.

15. The method of claim 14, wherein the method is implemented by application processing component of an electrical meter.

16. The method of claim 14, wherein the first analog-to-digital converter is part of the metrology component and the second analog-to-digital converter is external to the metrology component.

17. The method of claim 14, wherein the power consumption data is computed using a first signal processing component of the metrology component and the first information is determined using a second signal processing component that is external to the metrology component.

18. The method of claim 14, wherein the power consumption data is computed by processing the analog sensor signal with the first analog-to-digital converter.

19. The method of claim 14, wherein the power consumption data is computed by processing a second analog sensor signal, from a second electrical sensor, with the first analog-to-digital converter.

20. The method of claim 14, wherein the first information comprises one or more of information about operation of an electrical grid connected to the electrical meter, information about a location of a power outage, identifying information about a first device in the building, information about a state change of a first device in the building, energy consumption of a first device in the building, or energy consumption of a second device in the building.
